(19) United States
(12) Patent Application Publication
(10) Pub. No.: US 2005/0013337 A1
(43) Pub. Date: Jan. 20, 2005

(54) Semiconductor injection locked lasers and method

(76) Inventors: Thomas Jung, Rolling Hills Estates, CA (US); Kang-Yih Liou, Holmdel, NJ (US); Hyuk-Kee Sung, Los Angeles, CA (US); Denis Tishinin, Somerset, NJ (US); Won T. Tsang, Holmdel, NJ (US); Ming C. Wu, Pacific Palisades, CA (US)

Correspondence Address: TESTA, HURWITZ & THIBEAULT, LLP, HIGH STREET TOWER, 125 HIGH STREET, BOSTON, MA, 02110, US

(21) Appl. No.: 10/855,799

(22) Filed: May 27, 2004

Related U.S. Application Data
(60) Provisional application No. 60/474,570, filed on May 30, 2003.

(51) Int. Cl. H01S 5/00; H01S 3/14

(52) U.S. Cl. 372/50; 372/68

(57) ABSTRACT

In one aspect, the invention relates to a semiconductor laser. The laser includes a substrate and an elongate unitary laser structure disposed on the substrate. In turn, the elongate unitary laser structure includes a first laser section, a second laser section, and a plurality of shared layers. The first and second laser sections are capable of lasing independently of each other. The shared layers form both the first laser section and the second laser section. The first laser section is adapted for injection locking the second laser section.

### CROSS-REFERENCE TO RELATED APPLICATIONS

This application claims the benefits of provisional U.S. patent application Ser. No. 60/474,570 filed on May 30, 2003, the disclosure of which is hereby incorporated herein by reference in its entirety.

### GOVERNMENT SUPPORT

This invention was made with Government support under Grant No. DAAD17-01-C-0077, awarded by the DARPA RFLICS Program. The Government has certain rights in this invention.

### FIELD OF THE INVENTION

The invention relates generally to the field of lasers. Specifically, the invention relates to semiconductor lasers and injection locking techniques.

### BACKGROUND OF THE INVENTION

The development of optical fiber based communication systems has led to numerous advances over conventional wire based technology. In particular, increases in available bandwidth have made new services and applications possible. Some of these increases in bandwidth derive from the ability to multiplex multiple channels of information. In turn, it is laser modulation that facilitates multiplexing light-based signals in optical fibers. Directly modulated semiconductor lasers are of particular interest in various analog fiber-optic applications. Some of these applications include cable television (CATV) distribution systems, antenna remoting, cellular networks, and high-bit rate (40 Gbit/s) very-short-reach (VSR) optical links.

In some of these applications, the nonlinearity and low modulation bandwidth of the semiconductor lasers limit the performance of the fiber-optic systems. In order to achieve higher bandwidth and improved fidelity, other approaches must be considered. Optical injection locking has been found to be an effective method to improve modulation characteristics. Accordingly, injection-locking theory may provide an approach for further improving telecommunication system bandwidth.

However, injection locking laser systems have generally been restricted to the laboratory environment. This restriction exists because experiments involving injection locking typically require two separately packaged lasers. Further, achieving a stable injection-locked state requires the precise selection and control over various laser parameters such as the operating wavelength, the polarization values and the injection power ratio between the two lasers. Generally, a laboratory environment has been required for precise control over these parameters.

For strong injection locking, the output power from the master laser (Pᵢₙⱼ) is generally maintained at a level close to or greater than that of the slave laser (Pₒᵤₜ). Thus, an optical amplifier is often incorporated in the laboratory system to boost the master laser power to achieve a high injection ratio (Pᵢₙⱼ/Pₒᵤₜ). However, light losses and optical coupling efficiency can impact the maximum injection ratio.

Therefore, the master laser is usually isolated from the slave laser using optical isolators to prevent optical feedback from the slave laser to the master laser. Various system elements are typically used to control the light exchange between the master laser and the slave laser. Additionally, the polarization of the light emitted from the master laser is typically aligned with that of the slave laser to achieve injection locking. Thus, lenses, optical fiber, and a polarizer are typically required for coupling between the two lasers.

Configuring and mounting these various system components on an optical bench further limits the portability of injection locked lasers. Although suitable for research applications, large-scale multi-component laser systems are not suitable for many applications outside the laboratory. In particular, the size constraints and the need for multiple optically linked system elements render these configurations impractical for many telecommunications applications.

Consequently, a need exists for techniques and devices that enable the broader application of injection locking technology. Further, techniques are sought that provide improved frequency control and bandwidth without significantly increasing fabrication costs.

### SUMMARY OF THE INVENTION

In one aspect, the invention relates to a semiconductor laser. The laser includes a substrate and an elongate unitary laser structure disposed on the substrate. In turn, the elongate unitary laser structure includes a first laser section, a second laser section, and a plurality of shared layers. The first and second laser sections are capable of lasing independently of each other. The shared layers form both the first laser section and the second laser section.

In one embodiment of this aspect, the first laser section is adapted for injection locking the second laser section. At least one laser section is wavelength tunable for one embodiment of this aspect of the invention. In another embodiment, an operating wavelength of the first and second laser sections is tuned to achieve optical injection locking. In one embodiment, the first laser section is electrically addressable through a first contact region disposed on the unitary structure and the second laser section is electrically addressable through a second contact region disposed on the unitary structure. In this embodiment, the second contact region is adjacent to and electrically isolated from the first contact region. In one embodiment, at least one laser section is a distributed feedback laser (DFB). In another embodiment, at least one laser section is a distributed Bragg reflector (DBR) laser. In still another embodiment, the shared layers include at least one electrical contact layer, an active layer, a waveguide layer, and at least one cladding layer.

In another aspect, the invention relates to a semiconductor laser that includes a substrate and an elongate unitary structure disposed upon a portion of the substrate. The structure includes a plurality of layers, the layers defining an active region. An end face for transmitting light is also part of the structure. Additionally, the structure includes a first contact region; and a second contact region isolated from the first contact region. The first and second contact regions are in electrical communication with the elongate unitary structure. Each contact region in electrical communication with a portion of the active region such that different portions of the active region are substantially electrically isolated and capable of independent stimulation by a respective contact region.

In one embodiment of this aspect, the first and second contact regions divide the elongate unitary structure into a first laser section and a second laser section such that the first laser section is adapted for injection locking the second laser section. In another embodiment of the invention, at least one laser section is a DFB laser. In another embodiment, at least one laser section is a DBR laser. In still another embodiment, the semiconductor laser further includes a grating, wherein the grating has a coupling coefficient and waveguide length product that range from about 0.7 to about 10. In another embodiment, the semiconductor laser includes at least one electrical contact layer, an active layer, a waveguide layer, and at least one cladding layer.

In yet another aspect, the invention relates to a method of injection locking a semiconductor laser. The method includes providing a single unitary semiconductor laser structure comprising a first laser section and a second laser section. Emitting light of a first wavelength from the first section in response to a first signal is one step in the method. Another step includes directing light of the first wavelength into the second section. The method also includes the steps of stimulating the second section with a second signal; and emitting light from the semiconductor laser in response to the first and second signals.

In one embodiment of this aspect, at least one laser section is a DFB laser. In another embodiment, at least one laser section is a DBR laser. In another embodiment, the first laser is adapted for injection locking the second laser section and the second laser section is modulated with electrical input signal for emitting light modulated in response to the input signal. In another embodiment, the electrical contact of the injection locked second laser is divided into two or more laser sections.

In various embodiments of the aspects of the invention, the operating wavelength of the two sections is current tuned to achieve optical injection locking; when locked the modulation bandwidth is increased from about 5 GHz to about 23 GHz.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 is a top perspective view of a schematic depicting a semiconductor laser according to an illustrative embodiment of the invention;

FIG. 2 is a top plan view of a laser device according to an illustrative embodiment of the invention mounted on a semiconductor laser carrier;

FIGS. 3A and 3B are schematic views depicting a transverse cross-sectional view and a longitudinal side view respectively, of portions of the illustrative embodiment depicted in FIG. 1, in which both laser sections are DFB lasers;

FIGS. 4A and 4B are perspective schematic views illustrating embodiments of the invention with accompanying electrical components according to an illustrative embodiment of the invention;

FIG. 5A is a simulated plot depicting the asymmetric injection locking range of an externally injection locked laser as known in the prior art;

FIG. 5B is a schematic depicting a frequency relationship between a master and slave laser section without an optical isolator according to an illustrative embodiment of the invention;

FIG. 5C is a plot depicting the wavelength spectrum for each laser section according to an illustrative embodiment of the invention;

FIGS. 6A and 6B are plots depicting frequency spectra for the laser under unlocked and injection locked conditions according to an illustrative embodiment of the invention;

FIG. 7 is a plot depicting laser modulation frequency responses according to an illustrative embodiment of the invention;

FIG. 8 is schematic diagram of an experimental setup for testing dual section lasers according to an illustrative embodiment of the invention;

FIGS. 9A-9D are plots depicting the relationship of various parameters relating to a semiconductor laser embodiment of the invention;

FIGS. 10A-10E are a series of transverse cross-sectional schematic views illustrating fabrication techniques according to an embodiment of the invention; and

FIGS. 11A-11B are schematic diagrams depicting an exemplary fabrication method for a device according to an illustrative embodiment of the invention.

### DETAILED DESCRIPTION

The presently preferred and alternative embodiments of the invention, including the best mode for practicing the invention known at this time, are now described in detail in connection with the accompanying drawings. It is, however, expressly noted that the present invention is not limited to these embodiments, but rather the intention is that modifications that are apparent to the person skilled in the art and equivalents thereof are also included.

In part, aspects of the invention are designed to improve semiconductor laser bandwidth, noise reduction, and linearity without significantly increasing manufacturing cost. Such results may be achieved through monolithic injection locked laser embodiments that incorporate coupled lasers in tandem. Specifically, a single unitary structure has been developed that enables the benefits of injection locking without using two, physically separate lasers as part of a larger optical system. Thus, in part, the invention relates to a unitary injection-locked laser with at least two separate gain sections. The details of the overall laser structure, methods of fabrication, experimental results, and various alternative embodiments are discussed in more detail below.

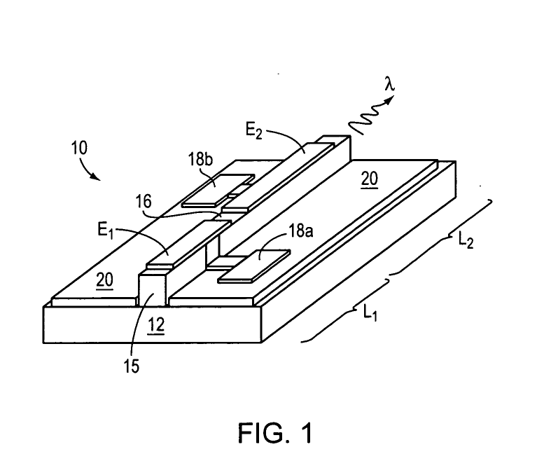

FIG. 1 shows a semiconductor laser 10 according to one aspect of the invention. This device 10 can be fabricated on a substrate 12 using various semiconductor techniques known to those of ordinary skill in the art. The device 10 includes an elongate unitary laser structure 15 as discussed below. The unitary structure 15 is disposed upon the substrate 12 to form a waveguide structure with optical gain sections for laser oscillation. The elongated unitary structure 15 includes a first laser section L₁ and a second laser section L₂ such that at least a portion of the structure 15 serves as a waveguide for both laser sections. Although, the device 10 is divided into different functional sections, those sections are fabricated using layers that run the length of the unitary structure 15. In various embodiments, at least one grating having a coupling constant K is disposed within the unitary structure 15.

The term unitary is used with respect to the structure 15 because although the structure incorporates sections having different functionalities, the structure 15 is a single elongate element formed from an arrangement of selectively formed layers and regions. Although various differently doped and undoped layers and regions are used to fabricate the semiconductor laser embodiments, some of the doped layers include an N-type material or a P-type material.

An N-type material generally has an increased level of free electrons as a result of the inclusion of a suitable dopant. Conversely, a P-type material has an increased level of free holes as a result of the inclusion of a suitable dopant. Suitable unitary structure layer materials include, but are not limited to: Indium Gallium Arsenide (InGaAs), Indium Gallium Arsenide Phosphide (InGaAsP), Indium Phosphide (InP), Aluminum Gallium Indium Arsenide (AlGaInAs), Aluminum Gallium Arsenide (AlGaAs), Silicon, Silicon Nitride, Silicon Dioxide, quantum well fabrication materials, other suitable semiconductor materials and dopants, and combinations thereof.

The layers and regions are appropriately shaped, positioned, and doped to allow for the amplification and emission of light within the structure in response to electrical stimulation. In one embodiment, the layers and regions that form the overall unitary structure span both lasers sections L₁, L₂. In another embodiment, one or more different layers may be used to fabricate each laser section L₁, L₂. The different layers within each section can be any undoped or doped layers suitable for fabricating a semiconductor light-emitting device.

As shown, the first laser section L₁ and the second laser section L₂, share a common waveguide layer for transmitting light of a specified wavelength λ. Accordingly, both laser sections are automatically aligned along the waveguide and share a common laser polarization. The problems of optical alignment and polarization matching that would occur in a conventional injection locking laser configuration are thus avoided in the embodiments disclosed herein.

Additionally, each laser section typically incorporates a grating that is incorporated in the unitary structure. This allows each section to act as a distributed feedback laser or alternatively as a distributed Bragg reflector in different embodiments. More importantly, the grating contributes to the attainment of optical injection locking by enabling each laser section to operate independently.

For each section to lase independently, a suitable grating is chosen such that a shorter gain length is required to reach the lasing threshold. Increasing the distributed feedback is analogous to decreasing the mirror loss so that a shorter cavity can be used. In order to evaluate cavity sizes in various embodiments, a unitary structure of length L having a grating with a coupling constant K can be analyzed in terms of the KL product. For devices with a small KL product, current tuning in each section fails to achieve independent operation at two distinct wavelengths. Since the unitary structure is divided into two smaller lasing sections, it follows that given a reduced L value for each lasing section, increasing the KL product requires increasing the coupling constant K value. Thus, gratings with higher coupling coefficients are particularly suited for various embodiments of the invention.

For a device having a unitary structure of length L and a grating having a coupling constant K, in one embodiment the grating is chosen such that the KL product ranges from about 3 to about 4. In one embodiment the device length L is approximately 750 μm. In other embodiments the device length L ranges from about 500 μm to about 1000 μm. In various embodiments the KL product ranges from about 0.7 to about 10. In other embodiments, the length L each laser section L₁, L₂ can be increased to offset smaller K values.

As discussed above, both laser sections L₁, L₂ can lase independently by incorporating additional optical elements, such as a grating, to alter the characteristics of each section. However, the independent lasing feature of each section is also facilitated through independent electrical control over both laser sections L₁, L₂. Although each laser section shares some or all of the structure's 15 plurality of selectively arranged layers, it is the placement and size of the electrical contact regions E₁, E₂ that further differentiate and define the two laser sections L₁, L₂. Additionally, the controlled introduction of electrical currents to these contact regions enables optical injection locking by selective tuning different input currents. Varying the electrical stimulation at one or both contact regions E₁, E₂, can also be used to modulate the transmitted light.

The electrical contact regions E₁, E₂ are in electrical communication with one or more of the constituent layers of the unitary structure 15. These electrical contact regions E₁, E₂ are separated by an isolation region 16. This isolation region can be formed by selectively etching a larger contact region and the underlying layers to electrically isolate the two resultant regions E₁, E₂. In one embodiment, dividing the contact regions and underlying layers results in over 1 KΩ of electrical isolation between the laser sections. The electrical contact regions can include, but are not limited to various suitable conductive metals and materials such as Ti, Pt, Au, Ag, Sn, Cu and combinations thereof. Other electrical contacts used in different embodiments and positioned at different locations of the device can also include, but are not limited to one or more of these conductive metals.

Generally, the sizes of the contact regions E₁, E₂ are approximately equal. However, the regions E₁, E₂ can be differently sized in one embodiment. Optional, auxiliary electrical contact regions 18a, 18b can also be used to facilitate electrically connecting the contact regions E₁, E₂ to voltage sources, current sources, signal sources, and other suitable electrical circuits and components. These auxiliary electrical contact regions are typically disposed on a larger passivation layer 20.

The passivation layer 20 protects the underlying layers from damage and contamination. In some embodiments the passivation layer may include silicon dioxide or silicon nitride. The passivation layer 20 can also be used to provide electrical insulation between the underlying layers and the metal contact on top to prevent unwanted electrical current leakage. Additional details relating to electrical stimulation of the laser sections L₁, L₂ are discussed in more detail below.

Embodiments of the invention can be fabricated in a standard semiconductor laser production facility. Further, the products of existing semiconductor laser producers can be redesigned using the approaches taught herein to create various injection locking laser embodiments. The semiconductor laser device embodiments disclosed herein are formed using various semiconductor materials arranged in layers, sections, and regions that appropriately doped for a given functionality. The individual laser devices 10 that result are typically manufactured from a localized region of a larger semiconductor wafer. Wafer based manufacturing techniques facilitate large-scale fabrication of semiconductor injection lockable devices for use in various industries.

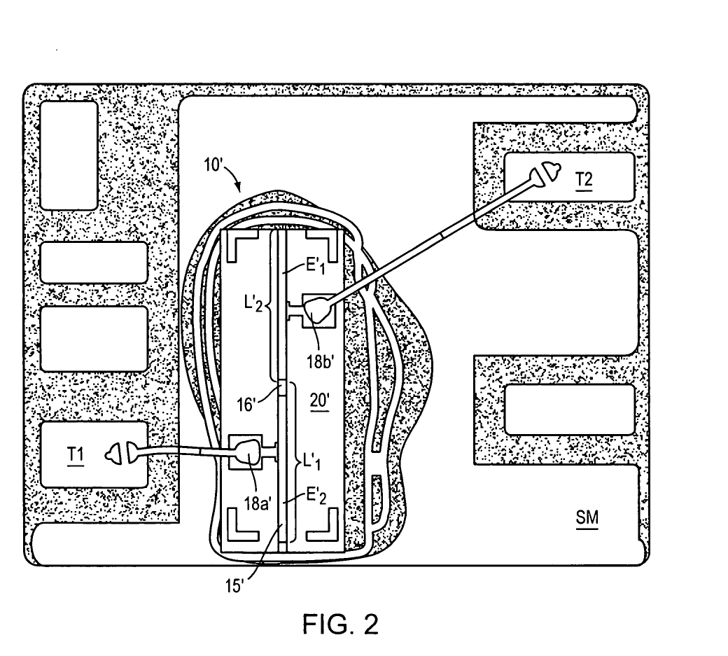

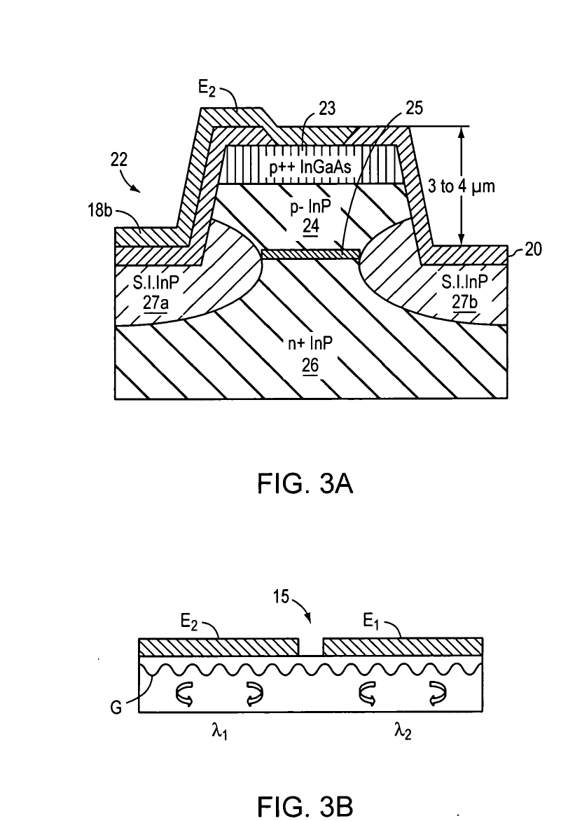

FIG. 2 shows an embodiment of the device 10 depicted in FIG. 1. The device 10′ embodiment shown in FIG. 2 has been fabricated from a silicon-doped indium phosphide substrate wafer using various semiconductor deposition techniques and etching processes. Accordingly, FIG. 2 shows an integrated master-slave laser structure 15′ on a submount SM with electrical terminations T1, T2 for current injection or direct modulation of both laser sections L₁′, L₂′. The particular details of fabricating a device embodiment 10, 10′ are discussed in more detail below. However, in order to describe the internal layer details of the device embodiments 10, 10′ shown, an exemplary cross-sectional view of a laser section is discussed in more detail below in FIG. 3A.

FIG. 3A illustrates an exemplary layer arrangement for an embodiment of the device 10 shown in FIG. 1. The general shape of the cross-section 22 and component layers indicates the capped mesa buried heterostructure nature of the device 10. The cross-sectional portion 22 shown represents an interior view of the layers of a portion of the elongate structure 15 shown in FIG. 1. Specifically, a portion of the first laser section L₂ viewed along a direction perpendicular to the direction of emitted light λ is shown. The grating layer, not shown in FIG. 3A, is typically positioned adjacent to the active region 25 and can be fabricated either below or above the active region 25.

The contact region E₂ is shown in electrical communication with the unitary structure 15 and an optional auxiliary contact region 18a. In particular, the contact region E₂ is in electrical communication with laser section contact layer 23. In this embodiment the contact layer 23 is a p++ doped InGaAs layer. The p++ designation indicates that the layer is highly doped with p-type material. The increased p-type doping in the contact layer 23 improves the layer's conductivity by increasing the available electrons, effectively forming an ohmic contact with the metal.

Some or all of the contact layer 23 is etched in order to form the isolation region 16 shown in FIG. 1. In one embodiment, a gap of about 0.2-μm depth is etched between the laser sections to achieve electrical isolation. The resistance between laser sections is greater than 4 kΩ as a result of the etching in various embodiments. The isolation region 16 serves as a dividing line between the two laser sections. Alternatively, the substrate 26 can also be a p-type material and in such an embodiment the contact layer 23 can be an n++ doped layer.

Thus, an analogous arrangement of the layers shown in cross-section 22 is also present in laser section L₁, on the other side of the isolation region 16. These layers are disposed below the E₁ contact region. However, different layer arrangements, layer component materials, and dopants can be used in different embodiments.

As shown in FIG. 3A, a top cladding layer 24, an active region 25, and a bottom cladding layer 26 are arranged below the contact layer 23. These various layers are bounded by Fe-doped semi-insulating Indium Phosphide current-blocking layers 27a, 27b on either size of the active region 25 as shown. The active region 25 typically includes multi-quantum well structures. Suitable materials for forming an active region 25 include, but are not limited to InGaAsP, InGaAs, AlGaInAs and AlGaAs.

In one embodiment, the top cladding layer 24 is a p-doped InP layer. The p-designation indicates that the layer that is lightly doped with a p-type material. The bottom cladding layer 26 is an n+ doped InP layer in one embodiment. The active region 25 is the area deposited within both laser sections wherein photons are emitted by recombination of electrons and holes. The active region 25 functions as a gain medium for each laser section. Accordingly, each laser section can lase at a different wavelength even though each section shares the same waveguide, grating, and active region.

The independent lasing of each laser section is possible, in part, because the electrical contact portions corresponding to each part of the active region are isolated. This is achieved by etching the contact layer 23 between each laser section. Generating a different current bias at each electrical contact results in a different lasing wavelength being emitted from each laser section. As such, selectively tuning the bias current for each section makes the injection locking phenomena possible. Additionally, changes in the bias current for each section allow each section to emit different wavelengths of light. In one embodiment where the laser is a DFB laser, the lasing wavelength can be tuned by the bias current or by temperature control. In another embodiment where the laser is a DBR laser, the lasing wavelength can be tuned by applying a bias current to the Bragg grating section of the DBR laser.

The active region 25 can include a stack of quantum well layers or a single bulk active layer. Accordingly, the active region 25 can itself serve as a waveguide layer. Alternatively, one or more additional passive layer(s) can be combined with the active region 25 to improve its waveguiding property. An additional passive waveguide layer can be in contact with or separate from the active region 25.

The top and bottom cladding layers 24, 26 and the left and right semi-insulating layers 27a and 27b can form part of the laser cavity in the lateral dimension for the unitary structure 15. In turn, distributed reflections from the DFB grating or reflection from the laser end facet define the laser cavity in the longitudinal direction. Light amplification occurs in the active region. A grating positioned above or below the active region introduces a periodic change in effective refractive index within the active region. Consequently, the refractive index change causes a distributed reflection according to the Distributed FeedBack (DFB) effect.

Additionally, although not shown, one or more additional electrical contact regions are disposed below the unitary structure 15. These bottom contact regions correspond to the E₁, E₂ regions disposed on top of the unitary structure. These bottom contact regions in conjunction with the top contact regions E₁, E₂ facilitate the creation of the electron hole pairs in response to electrical stimulation. The top and bottom contact regions are typically in electrical communication through the unitary structure 15. These bottom contact regions are discussed in more detail below.

FIG. 3A shows a sandwich of layers formed around the active region 25. The active region 25 is typically 1-μm-wide. However, other suitable widths are possible. Generally the active region's length is equal to or less than the length of the unitary structure. In the embodiment shown in FIG. 1, the active region 25 is bounded by the surrounding semi-insulating InP regions 27a, 27b. When the mesa structure is formed, etching down to the semi-insulating regions 27a, 27b reduces parasitic capacitance in the device. These two layers 27a, 27b are typically doped with a material, such as for example, iron (Fe), to increase the electrical resistance. Thus, they are considered “semi-insulating” layers. Additionally, these layer 27a, 27b can function as side cladding layers in some embodiments.

The active region 25 is disposed within the elongate structure 15 and spans both laser sections L₁, L₂. A waveguide layer (not shown) can be formed upon or under the active layer if desirable. The waveguide structure also spans the length of the unitary structure. Thus, the active region and the waveguide layer are deposited between the p-InP and n-InP cladding layers. The details of forming and etching the layers shown in FIG. 3A are discussed in more detail below.

Additionally, the cross-sectional portion 22 of the device 10 can include additional elements and structures, such a grating or a reflective element. FIG. 3B illustrates the placement of an exemplary grating G that spans the length of the unitary structure 15. This grating G enables the first laser section to emit light at λ₁ in response to a particular current I₁ while the second laser section can emit λ₂ in response to a particular second current I₂. The two wavelengths are determined, in part, by the grating period, effective indices of the laser cavities, and laser operation conditions.

The structural details of some embodiments of the invention have been introduced above in FIGS. 1-3B. The unitary structure 15, 15′ described above incorporates two laser sections that function as an injection lockable system wherein each laser section can operate independently of the other. This structural arrangement extends the benefits of injection locking to new areas outside the confines of a research environment.

The theory of injection locking applies generally to all oscillating systems and devices. The fact that a first oscillator can cause a frequency change in a second oscillator was first observed when clocks driven at different frequencies by their respective pendulums became synchronized. In that instance, frequency synchronization was achieved because the clocks were mounted on a common surface.

Similarly, the theory of injection locking that was subsequently developed extends to light based oscillators. Thus, one laser oscillator operating at a first wavelength may become coupled to a second laser oscillator operating at a second wavelength. The theory of laser injection locking teaches that two lasers can be arranged as a master-slave pair in order to control the frequency of the emitted laser light in order to reduce various negative modulation and mode related effects.

Specifically, when light from one laser section L₁ is introduced into the second laser L₂ section, the injection step, the second laser becomes substantially locked to the same frequency as the first laser. Since chirping generally refers to a rapid change in the emission wavelength of an optical source that occurs when a laser source is pulsed, the frequency control achieved using injection locking can reduce chirp. In turn, this improves laser modulation efficiency. Additionally, other benefits of injection locking include increased modulation bandwidth, increased linearity, and lower noise.

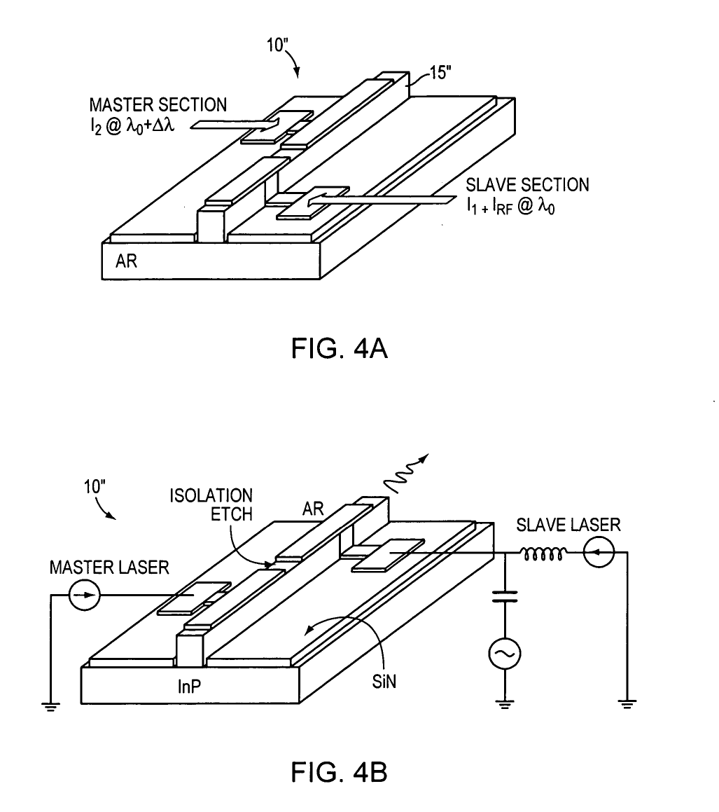

In FIGS. 4A and 4B, another semiconductor laser device 10″ embodiment is shown with some accompanying electrical components. The slave laser section of the unitary structure 15″ can receive a first current I₁ and an accompanying radio frequency signal current I_{RF} such that the slave section emits light at a baseline wavelength of λ₀. The RF signal current allows the light emissions of the device 10″ to be modulated. The master laser section of the unitary structure 15″ is shown receiving an exemplary second current I₂. Accordingly, the master section emits light at a wavelength approximately equal λ₀+Δλ. The difference between the wavelength emitted from the master and laser sections, Δλ, is a function of the relationship between the respective laser section currents I₁, I₂. In various embodiments, these currents and other parameters may be tuned to achieve injection locking. In one embodiment, an anti-reflection (AR) coating is deposited on one facet of the substrate to minimize the Fabry Perot modes of the cavity. This anti-reflection (AR) coating has a reflectivity of less than 0.1% in one embodiment.

In FIG. 4B, various current sources, inductive elements, and signal source are shown for one embodiment of the invention. The elements shown in FIG. 4B can be used to selectively address the unitary structure 15″ with different electrical signals. These signals can be used to test, modulate, and/or injection lock the device to a desire wavelength in various embodiments.

In a two-section DFB laser with properly selected gratings, each section can lase by itself. This concept is illustrated by the differing wavelengths discussed above with respect to FIG. 3B. Locking/unlocking phenomenon between the modes of individual sections was observed by tuning the bias current on each laser section. When biased within the proper current range, the two sections operate at the same wavelength and exhibit a significant increase in the modulation bandwidth, similar to optical injection locking with external master lasers. In addition, the nonlinear distortions such as second harmonic and inter-modulation distortions are also suppressed. This nonlinear distortion suppression phenomena is discussed in more detail below.

Additionally, the degree of coupling between the different sections of the unitary structure allows each section to behave like an individual laser. This coupling is controlled, in part, by the grating disposed within the waveguide portion of the device that spans both laser sections. Tuning the current (or wavelength) of one section of the laser structure facilitates that first laser section being optically injection locked to a second laser section of the unitary structure.

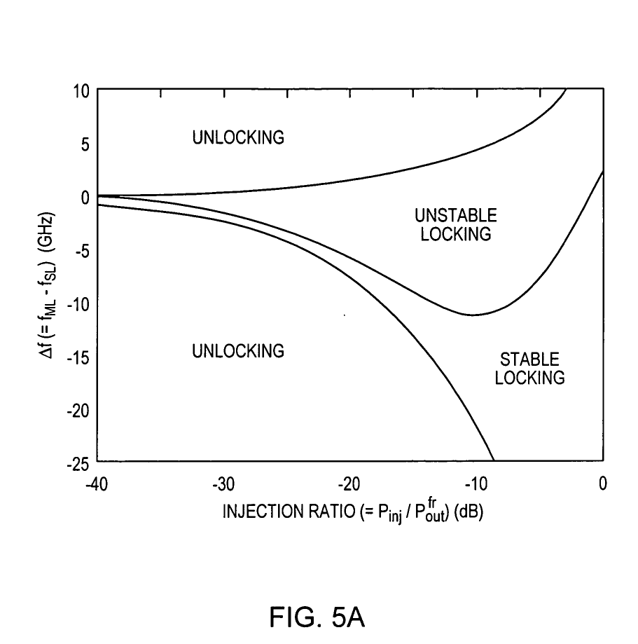

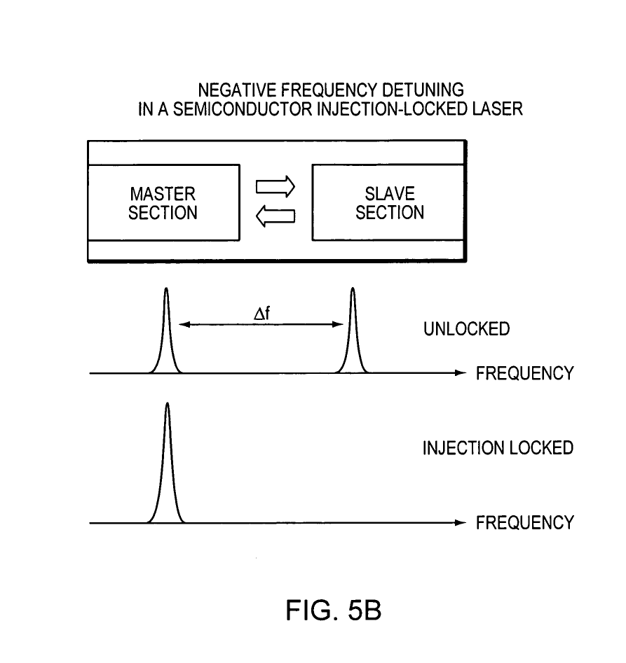

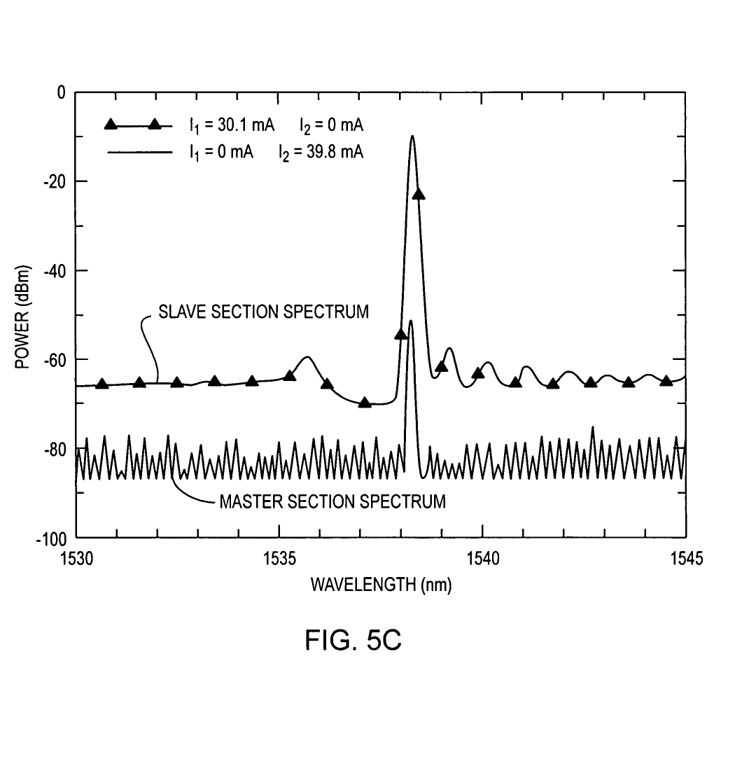

Specifying which laser section will function as a master and which section will function as a slave is determined based upon each laser's emitted wavelength. Specifically, it can be demonstrated that it is more stable for a longer-wavelength laser to injection lock a shorter-wavelength laser. This result is shown from theoretical analysis in FIG. 5A and described in more detail below.

FIG. 5A is a simulated plot of injection locking ranges using two separate lasers wherein the frequency detuning value Δf is plotted against the injection ratio. As shown, the unstable locking, the stable locking, and the unlocking regions in the plot demonstrate the asymmetric nature of the locking ranges. Because of the asymmetric stable locking range as shown in FIG. 5A, one of the lasers which lases at the lower frequency (f_{ML}) can lock the other laser which lases at higher frequency (f_{SL}). For example, the frequency detuning values (frequency of master laser—frequency of slave laser) suitable for stable injection locking ranges from about −7 GHz to about −40 GHz at a given injection ratio of −5 dB. Therefore, a laser operating at the lower frequency (longer wavelength) can operate as master laser. As a result, it is easier for one laser with a longer wavelength (smaller frequency) to lock the other having a shorter wavelength (higher frequency) but not the other way around. Therefore, the laser section that has a longer wavelength is naturally selected as the master laser as depicted in the illustration in FIG. 5B.

The asymmetric injection-locking range, however, is only a characteristic of lasers with non-zero linewidth enhancement factor. In general, the refractive index of a semiconductor laser structure is a complex number, and the linewidth enhancement factor is the ratio of the change in the real part of the index to an associated change in the imaginary part of the index. In most cases, semiconductor lasers have non-zero linewidth enhancement factors.

When two lasers are used in a laboratory setting to achieve injection locking, an optical isolator is used to prevent optical feedback from the slave laser to the master laser. If an isolator is not used in the prior art approaches, unpredictable and different frequency drifting occurs between the two lasers as a result of the feedback between the master and slave lasers. As a result, when such frequency changes occur, injection locking becomes unstable or reverts to an unlocked state.

The dual laser section based approach of the invention eliminates the need for an optical isolator. The isolator is not required because the master-slave laser pair integrated on the same semiconductor chip is environmentally robust once it is operated in the stable injection-locking regime in FIG. 5A. The shared waveguide removes unpredictable feedback effects. FIG. 5B depicts optical spectra in terms of lasing frequency when a dual-section laser without an optical isolator is operated in unlocked and injection locked states.

Although the laser sections are designed for injection locking, they can also operate as individual lasers. The optical spectrum of each section with the other section turned off is shown in FIG. 5C. The master section corresponds to the lower curve while the slave section corresponds to the higher curve shown in the plot. The master section current I₁ is set to about 39.8 mA when the slave laser current is held at 0 mA. Conversely, the slave section current I₂ is set to about 30.1 mA when the master section current is 0 mA. The optical spectrum of the section furthest away from the output facet is attenuated by the unbiased section closest to the output facet; however nearly equal output power is achieved by measuring the output at the other facet.

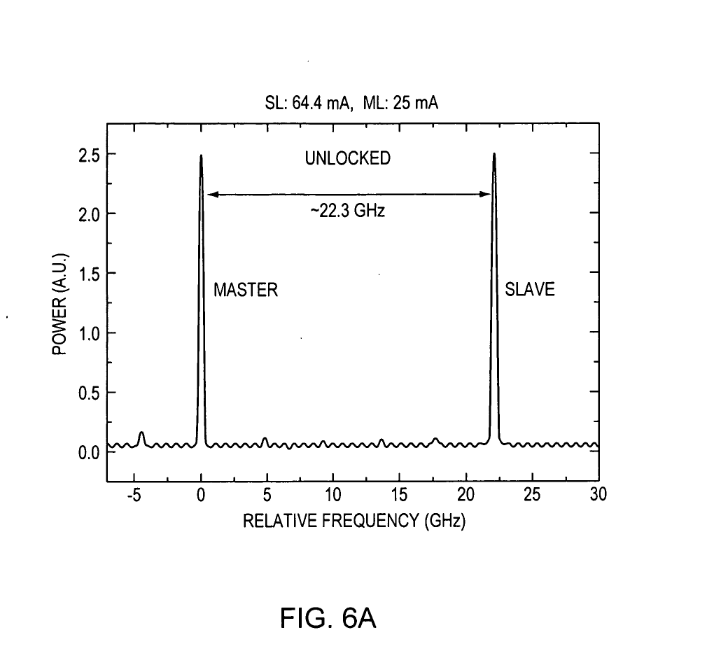

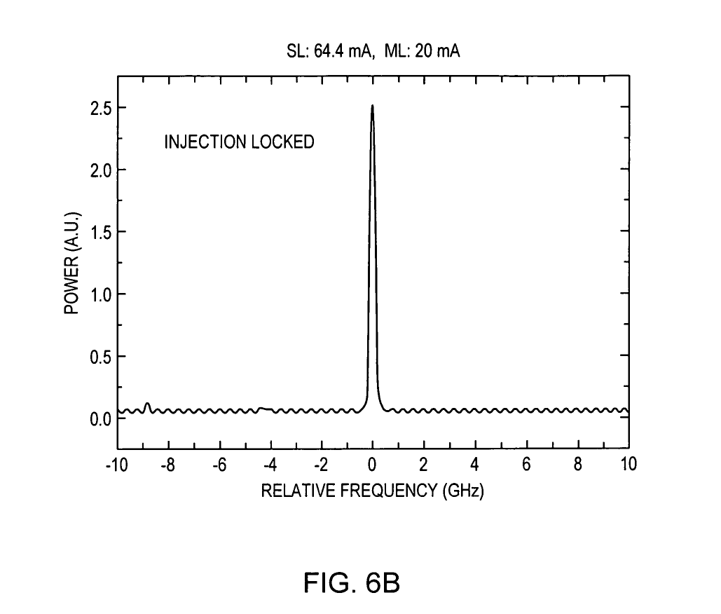

The operating optical frequencies of the two sections can be matched by current tuning. Since the two lasers are not isolated the locking range is very complex since both lasers will try to force the other to operate at its own frequency. Under unlocked condition, two discrete modes can be resolved (master and slave), as shown in FIG. 6A (Slave Laser (SL) section bias current=64.4 mA, Master Laser (ML) section bias current=25 mA). When tuned close to the locking range, the two discrete modes become locked and the output spectrum is a single line near the master laser frequency, as shown in FIG. 6B (Slave Laser (SL) section bias current=64.4 mA, Master Laser (ML) section bias current=20 mA). When the lasers are unlocked, optical beating between the two laser modes at their difference can be observed in the RF spectrum. The optical beating disappears when the lasers are injection locked.

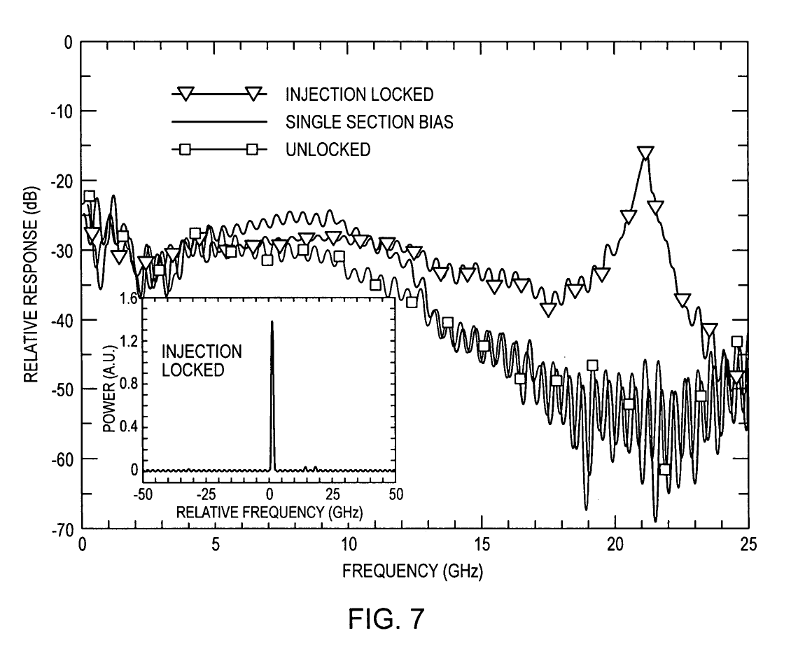

When optical injection locking is achieved, the modulation response of the laser shows a resonance peak of approximately 21 GHz and the measured optical spectrum indicates a single operating wavelength as shown in FIG. 7. The resonance peak is very broad compared to that of the unlocked state and is not due to optical modulation. The modulation responses for a single section bias and for an unlocked state (with large frequency detuning) are shown for comparison. The measured relaxation frequency is consistent with that obtained by using an external cavity tunable laser (ECTL) as a master laser and a single section DFB laser as a slave laser. Optical pumping outside the locking range does not improve modulation response. This indicates that the increased frequency of the resonance peak is related to the injection locking effect.

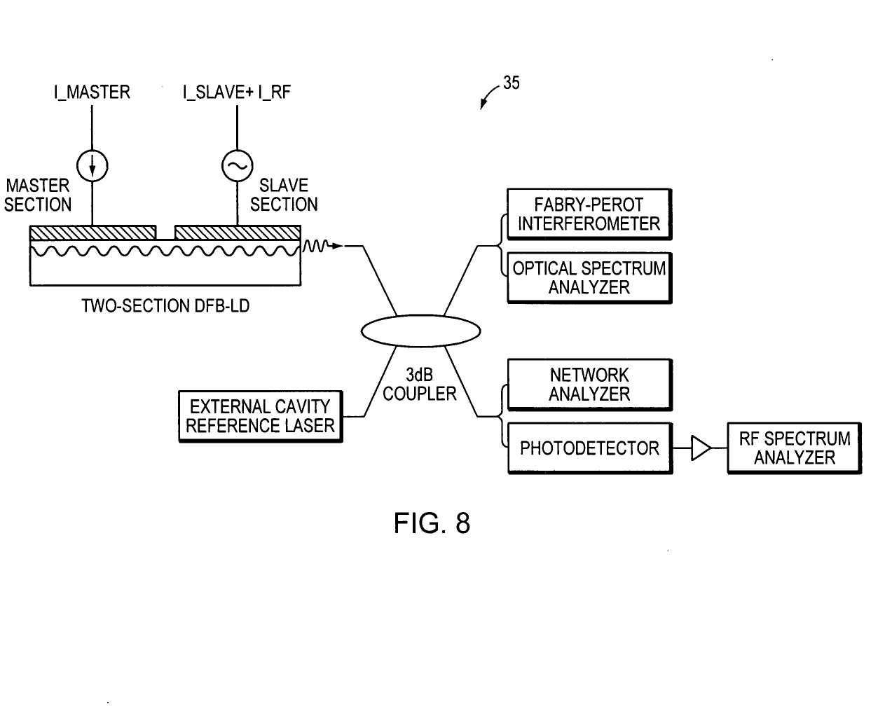

FIG. 8 illustrates an exemplary experimental setup 35 for measuring the optical spectrum, modulation response, and nonlinear distortion of the injection-locked semiconductor laser embodiments of the invention. This setup 35 is more compact than typical laboratory based injection locking experimental configurations that require an external light source. As a result of the design of the embodiments disclosed herein, the experimental setup 35 does not require polarization controllers, optical circulators (or isolators), and fiber connections to laser couplers.

An external cavity laser is used as a stable wavelength reference for measuring the current tuning characteristics of each mode. The wavelength of one of the laser sections is controlled such that the wavelength differs from the wavelength of the other laser section. These two different wavelengths are achieved when the device is in an un-locked state. The changes in wavelength and modulation rates for a given dual section laser embodiment can then be compared to reference laser. Thus, it is possible to characterize the optical spectrum of the laser for an unlocked and an injection-locked state using the setup of FIG. 8.

The system shown in FIG. 8 can also be used to measure RF modulated phenomena. In a frequency response and RF modulation characteristics measurement test, a DC current and an RF signal are applied to the slave section through a bias tee, while another DC current is applied to the master section. The modulated output taken from slave section is coupled into a high-speed photodetector (for example, a 34 GHz detector). The detected signal is amplified by low-noise RF amplifier with 20 dB gain and then observed by an RF spectrum analyzer or network analyzer. Thus, the modulation characteristics of a given laser embodiment can be analyzed in more detail.

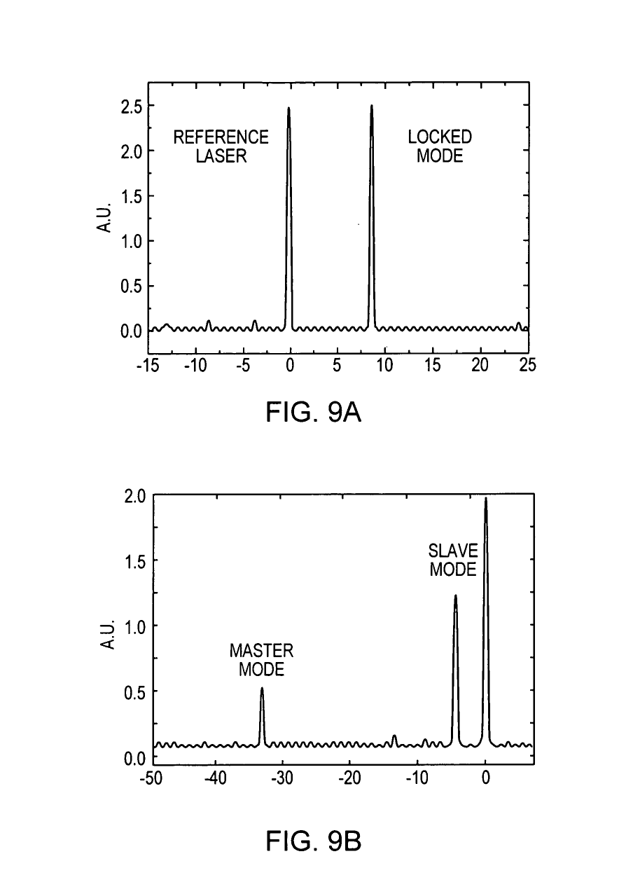

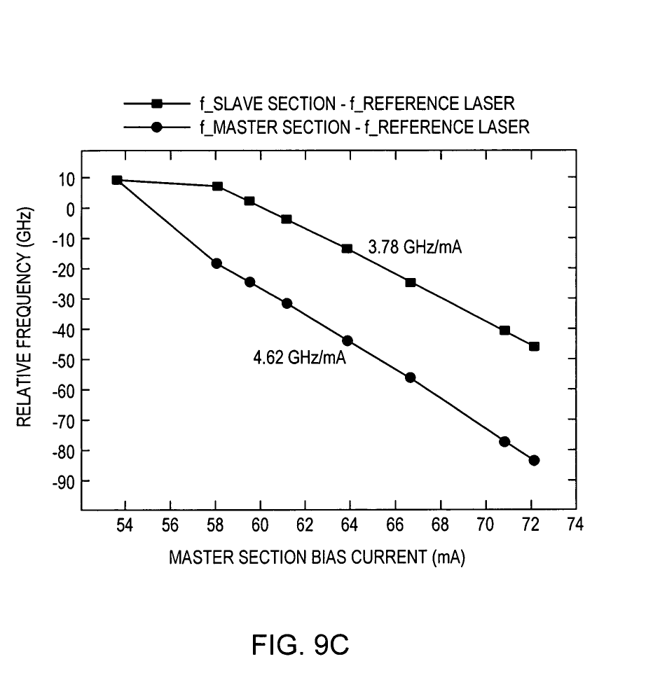

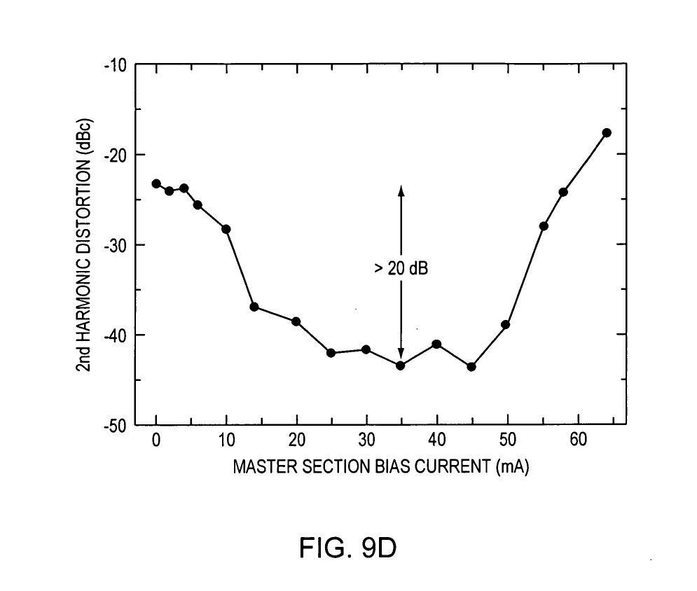

The high-resolution optical spectra of the two-section laser in obtained using the experimental setup 35 shown are shown in FIGS. 9A and 9B as measured by a scanning Fabry-Perot interferometer. A two section DFB laser, external cavity reference laser and a Fabry-Perot Interferometer as shown in FIG. 8 were used to observe the spectra shown. FIG. 9A illustrates an injection-locked state (master section bias=54 mA, slave section bias=45.2 mA). FIG. 9B illustrates an unlocked state (master section bias=61 mA, slave section bias=45.2 mA). In the injection-locked state, a single locked mode is observed at +9 GHz (compared to the reference laser). No other frequency components are observed in the injection locked state. However, in the unlocked state, the master and the slave section lase at two distinct wavelengths that are approximately 28 GHz apart.

FIG. 9C shows the relative frequency of the master and the slave sections versus the current of the master section for a specific embodiment. Specifically, the frequency (wavelength) dependence on the bias current is depicted in FIG. 9C. The slave section bias is fixed at 45.2 mA. As the master section bias current increases, both the master and the slave lasers move towards longer wavelengths due to heating effects.

The measurement, tuning rate is about 4.62 GHz/mA for the master laser section. The tuning rate for the slave laser section for which the bias current is fixed is about 3.78 GHz/mA. Therefore, based on these rates the wavelength of the master section can be tuned faster than that of the slave section. Thus, the master laser section current can be used to control the injection locking process. Frequency tuning in GHz/mA is same as wavelength tuning, thus 12.5 GHz corresponds to about 0.1 nm change in wavelength near 1550 nm.

The wavelength-tuning rate of the master laser is slightly larger than the slave laser. Therefore, as the master laser current decreases, the wavelength difference between the master and the slave lasers gradually decreases. As a result, the slave laser eventually enters the injection-locked state.

The monolithic optical injection-locking scheme is relatively straightforward to control. In one embodiment, there is only one tuning parameter, namely the master section current. Unlike external injection locked lasers, the monolithic injection locked laser is much less sensitive to ambient temperature since the wavelengths of both master and slave lasers drift in the same direction. Further, the frequency detuning between the sections remains constant.

Nonlinear behavior generally limits the utility of many communication devices. In particular, the predictable modulation behavior required in the digital telecommunications field or analog optical fiber links may render a device useless for a particular application if distortion effects predominate. A linearly responsive device improves the ability to modulate signals such that the signals can be transmitted and received in fiber optic networks. The injection locking features of the invention have been shown to reduce various distortion effects.

FIG. 9D illustrates the measured second harmonic distortion versus master section bias current. The slave section is biased at about 45.2 mA and modulated by a 9 GHz RF signal. Generally, the severity of the nonlinear distortion increases as the modulating frequency approaches the relaxation oscillation frequency. This occurs because of nonlinear coupling between electrons and photons. Hence, if the resonance frequency of the laser is increased, the nonlinear distortions can be reduced while the modulation bandwidth is increased. To measure the second-harmonic distortion (2HD) the slave section is modulated by a single tone RF signal (f=9 GHz). The second harmonic product is at 18 GHz. To investigate the 2HD in both locked and unlocked states, the slave laser current is fixed at 45.2 mA and the master laser section current is varied from 0 mA to 65 mA. Stable optical injection is observed between 14 mA to 53 mA. As FIG. 9E indicates, during the injection locked state, the second harmonic RF power is reduced by more than 15 dB compared to the free-running and unlocked state. Thus, in addition to the modulation benefits of the invention, distortion is reduced over the applicable injection locking current range.

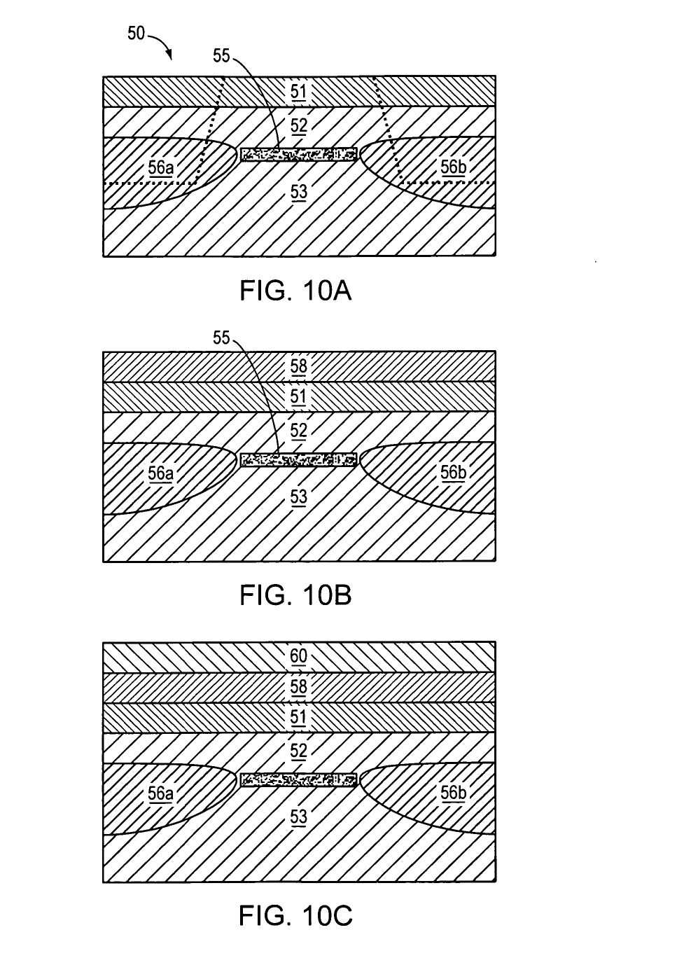

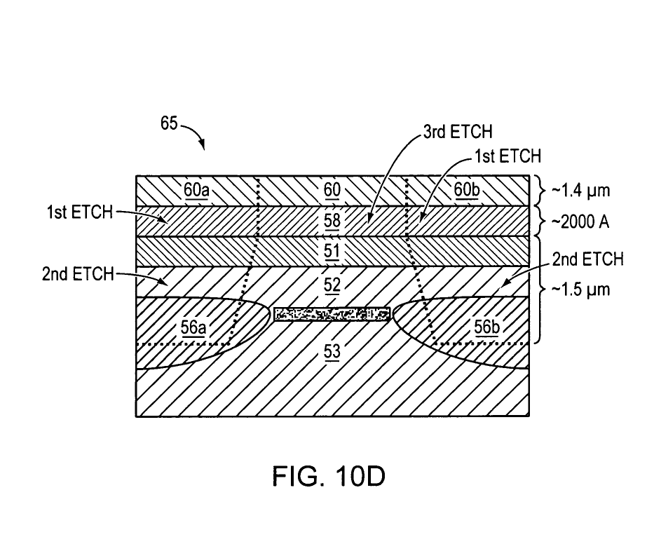

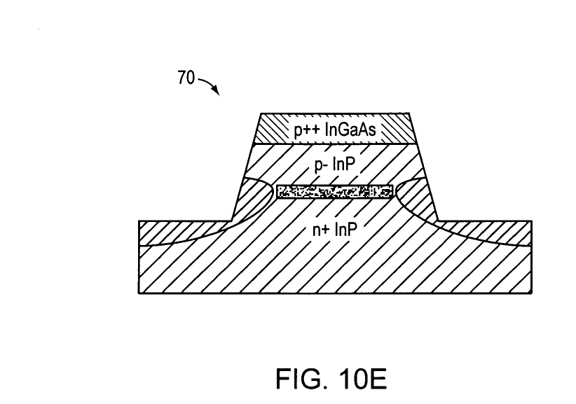

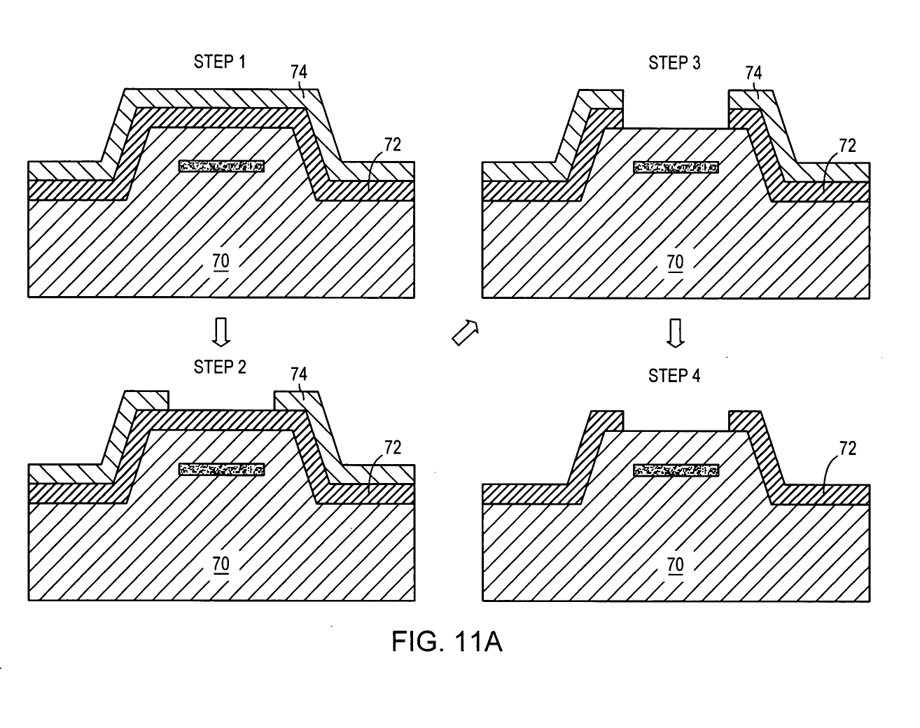

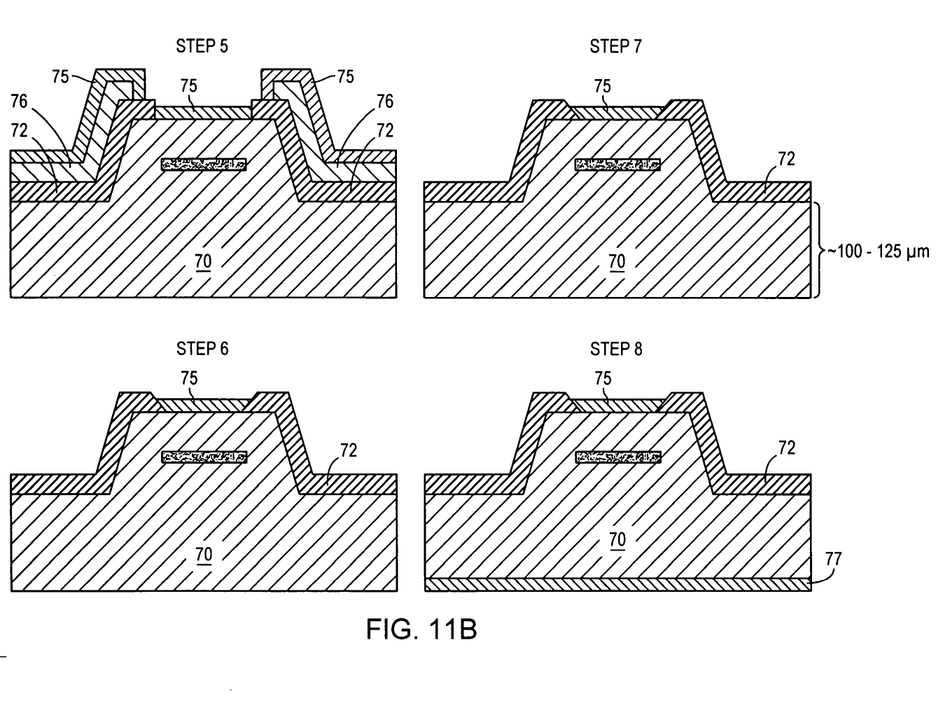

The structural and electronic features of the invention and various experimental results have been explored in more detail in the sections outlined above. Another benefit of the invention is the ease within which it can be fabricated using conventional semiconductor processes. An exemplary fabrication process is discussed in more detail below with respect to FIGS. 10A-10E and FIGS. 11A-11B.

FIG. 10A shows a portion of semiconductor wafer that has undergone preprocessing resulting in the formation of various selectively doped layers and regions within the substrate portion 50. Further processing of the substrate portion 50 according to some of the steps outlined below will result in the creation of a dual section injection lockable semiconductor laser device. The dotted lines in FIG. 10A delineate the mesa like etch profile that will eventually shape the unitary structure embodiments illustrated in FIGS. 1-3B.

The substrate portion 50 shown in FIG. 10A includes a laser section contact layer 51. A top cladding layer 52 and a bottom cladding layer 53 are also formed within the substrate portion 50 as shown. Further, a multi-quantum well active region 55 is also deposited on the substrate during wafer preprocessing. Two insulating regions 56a, 56b also bound the active region 55 as shown. Additional layers are typically formed upon the substrate portion 50 prior to initiating multiple etching steps.

In FIG. 10B the formation of an oxide layer 58 upon the contact layer 51 is shown. The oxide layer is used as a temporary passivation layer. Additionally, the oxide layer 58 is included to control the final device geometry when an etch is applied to the overall structure. Following the oxide layer 58 disposition, a photoresist layer 60 is typically formed upon the oxide layer as shown in FIG. 10C. In one embodiment, the oxide layer 58 includes silicon dioxide.

Turning to FIG. 10C, photoresist 60 is formed upon the oxide layer of 58. In one embodiment, the photoresist layer is approximately 1.4 micrometers in thickness. In various embodiments, either a positive or negative photoresist can be used. The photoresist is chemically developed after being selectively patterned through a mask. After patterning and development, portions of the photoresist layer are removed.

In FIG. 10D, the photo resists layer portions 60a, 60b are selectively patterned and portions of the substrate material in those regions are removed to achieve the etch pattern profile indicated by the dotted lines. The remaining photoresist layer 60 remains and limits the exposure of some of the layers to the subsequent etch processes. In turn, the controlled shaping caused by the photoresist layer 60 will facilitate the formation of a mesa shaped unitary laser structure.

The arrangement of layers 65 shown in FIG. 10D is exposed to a series of selective etches while the patterned photoresist material shields the core layers that will form the unitary structure. A first etch is applied to the exposed portions of the oxide layer 58. A reactive ion etch using fluorine chemistry can be used as part of the first etch. A controlled second etch is then performed on the contact layer 51 and the insulating regions 56a, 56b. A hydrogen bromide etch is used for the second etch in on embodiment. After the second etch the remaining photoresist layer 60 is removed and the oxide layer 58 is removed. The oxide layer 58 is typically etched with a fluorine based reactive ion etch or a buffered oxide etch.

Once these steps are complete a finished laser structure 70 results as shown in FIG. 10E. One or more electrical contacts are added to the laser structure 70 through additional processing steps. Additionally, portions of the structure 70 are also typically passivated with a suitable material such as silicon dioxide or silicon nitride. These additional steps are discussed in more detail with respect to FIGS. 11A and 11B.

FIG. 11A shows the formation of a passivation layer 72 and a photoresist layer 74 upon the previously formed laser structure 70 (Step 1). In one embodiment the passivation layer is approximately 5000 Å thick. Once the layers are in place a portion of the photoresist 74 layer is removed (Step 2). Additionally, a portion of the passivation layer 72 is removed (Step 3) before the remaining photoresist layer 74 is removed (Step 4). These removal steps are typically performed using a suitable etch process. These steps leave a portion of the unitary structure exposed for the introduction of a metal or suitably doped electric contact material.

FIG. 11B shows the introduction of a p-type contact metal 75 (Step 5). In some embodiment, an optional photoresist layer 76 is also formed prior to the deposition of the contact metal 75. A lift off process (Step 6) is used to remove any of the contact metal 75 outside the bounds of the passivation layer 72. Additionally, the isolation etch of the p++ InGaAs layer is typically performed at this stage to divide the two laser sections and achieve electrical isolation exceeding 4 kw. In order to ensure that the thickness of the substrate portion and the unitary structure is appropriate for a given application a lap process is used to remove excess substrate materials (Step 7). The lap process also serves to smooth and prepare the bottom surface of the device for further processing.

A bottom electrical contact 77, typically a n-type material is deposited on the bottom surface of the substrate materials as shown (Step 8). This contact layer 77 facilitates the electrical connections to the top and bottom portion of the semiconductor structure discussed above. In some embodiments, the bottom metal contact layer is etched to form an isolation region between the two laser sections. In some embodiments the bottom contact layer may include, but is not limited to Au, Sn, Au, suitable conductive materials, and combinations thereof. In some embodiment, the contact metal 75 can be an n-type material and the contact layer 77 can be a p-type material.

The fabrication steps outlined with respect to FIGS. 10A-11B allow for the production of various unitary laser structure based embodiments. Additionally etch steps may be used to divide the top contact layer into two or more contact regions. These contact regions may be of differing lengths and/or have areas of differing comparative rations. Thus, additional electrical contact regions in addition to the E₁, E₂ regions can be formed upon the unitary structure.

Dividing the unitary structure into individual electrically addressable regions has certain benefits. Specifically, the unitary structure can be divided into multiple regions to form a distributed Bragg reflector. Thus, an exemplary DBR embodiment can be fabricated that has a first laser section, a second laser section, a phase control section, and a grating section. In one embodiment the distributed Bragg reflector operates based upon the gain lever effect.

It should be appreciated that various aspects of the claimed invention are directed to portions of the devices described and substeps of the injection locking techniques disclosed herein. Further, the terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed. Accordingly, what is desired to be secured by Letters Patent is the invention as defined and differentiated in the following claims, including all equivalents.

1. A semiconductor laser, the laser comprising:
a substrate; and
an elongate unitary laser structure disposed on the substrate,
the elongate unitary laser structure comprising
a first laser section,
a second laser section, the first and second laser sections capable of lasing independently of each other, and
a plurality of shared layers, wherein the shared layers form both the first laser section and the second laser section.

2. The semiconductor laser of claim 1 wherein the first laser section is adapted for injection locking the second laser section.

3. The semiconductor laser of claim 1 wherein at least one laser section is wavelength tunable.

4. The semiconductor laser of claim 1 wherein an operating wavelength of the first and second laser sections is tuned to achieve optical injection locking.

5. The semiconductor laser of claim 1 wherein the first laser section is electrically addressable through a first contact region disposed on the unitary structure and the second laser section is electrically addressable through a second contact region disposed on the unitary structure, the second contact region adjacent to and electrically isolated from the first contact region.

6. The semiconductor laser of claim 1 wherein at least one laser section is a DFB laser.

7. The semiconductor laser of claim 1 wherein at least one laser section is a DBR laser.

8. The semiconductor laser of claim 1 wherein the shared layers comprise: at least one electrical contact layer, an active layer, a waveguide layer, and at least one cladding layer.

9. A semiconductor laser, the laser comprising:
a substrate;
an elongate unitary structure disposed upon a portion of the substrate,
the structure comprising a plurality of layers, the layers defining an active region;
an end face for transmitting light,
a first contact region; and
a second contact region isolated from the first contact region,
the first and second contact regions in electrical communication with the elongate unitary structure,
each contact region in electrical communication with a portion of the active region such that different portions of the active region are substantially electrically isolated and capable of independent stimulation by a respective contact region.

10. The semiconductor laser of claim 9 wherein the first and second contact regions divide the elongate unitary structure into a first laser section and a second laser section such that the first laser section is adapted for injection locking the second laser section.

11. The semiconductor laser of claim 10 wherein at least one laser section is a DFB laser.

12. The semiconductor laser of claim 10 wherein at least one laser section is a DBR laser.

13. The semiconductor laser of claim 10 further comprising a grating, wherein the grating has a coupling coefficient and waveguide length product that range from about 0.7 to about 10.

14. The semiconductor laser of claim 9 wherein the unitary structure comprises: at least one electrical contact layer, an active layer, a waveguide layer, and at least one cladding layer.

15. The semiconductor laser of claim 9 wherein a portion of the substrate is a laser cavity.

16. A method of injection locking a semiconductor laser, the method comprising
providing a single unitary semiconductor laser structure comprising a first laser section and a second laser section;
emitting light of a first wavelength from the first section in response to a first signal;
directing light of the first wavelength into the second section;
stimulating the second section with a second signal; and
emitting light from the semiconductor laser in response to the first and second signals.

17. The method of claim 16 wherein at least one laser section is a DFB laser.

18. The method of claim 16 wherein at least one laser section is a DBR laser.

19. The method of claim 16 wherein the first laser is adapted for injection locking the second laser section and the second laser section is modulated with an electrical input signal for emitting light modulated in response to the input signal.

20. The method of claim 19 wherein the electrical contact of the injection locked second laser is divided into two or more laser sections.
